(19) United States
(12) Patent Application Publication
(10) Pub. No.: US 2026/0259066 A1
(43) Pub. Date: Sep. 3, 2026

(54) SENSING ACTUATOR

(71) Applicant: Primax Electronics Ltd, Taipei (TW)

(72) Inventors: Wei-Chiang Huang, Taipei (TW); Wei-Ping Chan, Taipei (TW); Tse-Ping Kuan, Taipei (TW); Ming-Hui Yeh, Taipei (TW)

(21) Appl. No.: 19/409,487

(22) Filed: Dec. 4, 2025

(30) Foreign Application Priority Data
Mar. 3, 2025 (TW) 114107596

(51) Int. Cl. G01D 5/14; G01D 5/20

(52) U.S. Cl. CPC G01D 5/145; G01D 5/20

(57) ABSTRACT

The present disclosure provides a sensing actuator, which includes a housing, a vibration assembly, an elastic damping member and a displacement sensing assembly. The housing has an upper portion and a lower portion, the upper portion being movable downward relative to the lower portion. The vibration assembly is disposed in the housing. The elastic damping member is disposed in the housing and separated from the vibration assembly, the elastic damping member being configured to restore the upper portion to its original position after the upper portion moves downward. The displacement sensing assembly is disposed in the housing and separated from both the vibration assembly and the elastic damping member, in which the displacement sensing assembly is an eddy-current displacement sensing assembly or a Hall-effect displacement sensing assembly.

### FIELD OF THE INVENTION

The present disclosure relates to a sensing actuator.

### BACKGROUND OF THE INVENTION

Conventional actuators only provide mechanical motion and do not have sensing capabilities, making it impossible to achieve sensing and mechanical motion simultaneously. If an electronic device requires sensing functions, additional sensing components must be installed, which occupy extra space.

### SUMMARY OF THE INVENTION

The present disclosure provides a sensing actuator, which includes a housing, a vibration assembly, an elastic damping member and a displacement sensing assembly. The housing has an upper portion and a lower portion, the upper portion being movable downward relative to the lower portion. The vibration assembly is disposed in the housing. The elastic damping member is disposed in the housing and separated from the vibration assembly, the elastic damping member being configured to restore the upper portion to its original position after the upper portion moves downward. The displacement sensing assembly is disposed in the housing and separated from both the vibration assembly and the elastic damping member, in which the displacement sensing assembly is an eddy-current displacement sensing assembly or a Hall-effect displacement sensing assembly.

In some embodiments of the present disclosure, the upper portion of the housing is made of a conductive metal, and the displacement sensing assembly is the eddy-current displacement sensing assembly, and the eddy-current displacement sensing assembly includes: a coil, disposed on the lower portion of the housing and configured to be energized to generate a magnetic field, in which when the upper portion moves downward, the upper portion approaches the coil.

In some embodiments of the present disclosure, the displacement sensing assembly is the Hall-effect displacement sensing assembly, and the Hall-effect displacement sensing assembly includes: a coil, disposed on the lower portion of the housing and configured to be energized to generate a magnetic field; and a Hall element, coupled to the upper portion of the housing and corresponding to the coil, in which when the upper portion moves downward, the Hall element approaches the coil.

In some embodiments of the present disclosure, the vibration assembly includes: a permanent magnet, coupled to the upper portion of the housing; and a coil, disposed on the lower portion of the housing and corresponding to the permanent magnet.

In some embodiments of the present disclosure, the sensing actuator further includes a controller electrically connected to the coil of the vibration assembly, in which when a distance by which the upper portion moves downward reaches a predetermined value, the controller energizes the coil of the vibration assembly to generate a magnetic field, thereby causing the permanent magnet to vibrate and thus causing the upper portion to vibrate.

In some embodiments of the present disclosure, the elastic damping member is further configured to help stop the vibration of the upper portion after the upper portion vibrates.

In some embodiments of the present disclosure, the upper portion of the housing includes a receiving portion that receives the permanent magnet.

In some embodiments of the present disclosure, the eddy-current displacement sensing assembly or the Hall-effect displacement sensing assembly includes a coil, and the coil of the eddy-current or Hall- effect displacement sensing assembly surrounds the coil of the vibration assembly.

In some embodiments of the present disclosure, the eddy-current displacement sensing assembly or the Hall-effect displacement sensing assembly includes a coil, and the coil of the vibration assembly surrounds the coil of the eddy-current or Hall-effect displacement sensing assembly.

In some embodiments of the present disclosure, the eddy-current displacement sensing assembly or the Hall-effect displacement sensing assembly includes a coil, and the coil of the eddy-current or Hall-effect displacement sensing assembly is fixed to the lower portion of the housing.

### BRIEF DESCRIPTION OF THE DRAWINGS

Aspects of the present disclosure are best understood from the following embodiments, read in conjunction with accompanying drawings. However, it should be understood that in accordance with common practice in the industry, various features have not necessarily been drawn to scale. Indeed, shapes of the various features may be suitably adjusted for clarity, and dimensions of the various features may be arbitrarily increased or decreased.

FIG. 1 is an exploded view of a sensing actuator according to an embodiment of the present disclosure.

FIG. 2 is a sectional view of the sensing actuator shown in FIG. 1.

FIG. 3 is an exploded view of a sensing actuator according to another embodiment of the present disclosure.

FIG. 4 is a sectional view of the sensing actuator shown in FIG. 3.

FIG. 5 is a sectional view of a sensing actuator according to an embodiment of the present disclosure.

FIG. 6 is a sectional view showing an upper portion of a housing of the sensing actuator in FIG. 5 after being pressed downward.

### DETAILED DESCRIPTION OF THE PREFERRED EMBODIMENT

The advantages and features of the present disclosure and the method for achieving the same will be described in more detail with reference to exemplary embodiments and accompanying drawings to make it easier to understand. However, the present disclosure can be implemented in different forms and should not be construed as being limited to the embodiments set forth herein. On the contrary, for those skilled in the art, the provided embodiments will make this disclosure more thorough, comprehensive and complete to convey the scope of the present disclosure.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180°, the relationship between the one element and the other element may change from “beneath” to “over.” The spatially relative descriptions used herein should be interpreted the same.

As mentioned in the prior art, generally, conventional actuators only provide mechanical motion and do not have sensing capabilities, making it impossible to achieve sensing and mechanical motion simultaneously. If an electronic device requires sensing functions, additional sensing components must be installed, which occupy extra space. Accordingly, the present disclosure provides a sensing actuator that includes a housing, a vibration assembly, an elastic damping member, and a

displacement sensing assembly. The vibration assembly and the displacement sensing assembly are both disposed inside the housing, and the upper portion of the housing is capable of moving downward relative to the lower portion. The elastic damping member is provided to restore the upper portion to its original position after the upper portion moves downward. Therefore, the sensing actuator of the present disclosure can simultaneously achieve displacement (distance) sensing and mechanical motion. Compared with conventional actuators that rely on externally installed sensing components, the sensing actuator of the present disclosure requires no additional space, has lower cost, and features a relatively simple assembly process. Various embodiments of the sensing actuator of the present disclosure will be described below.

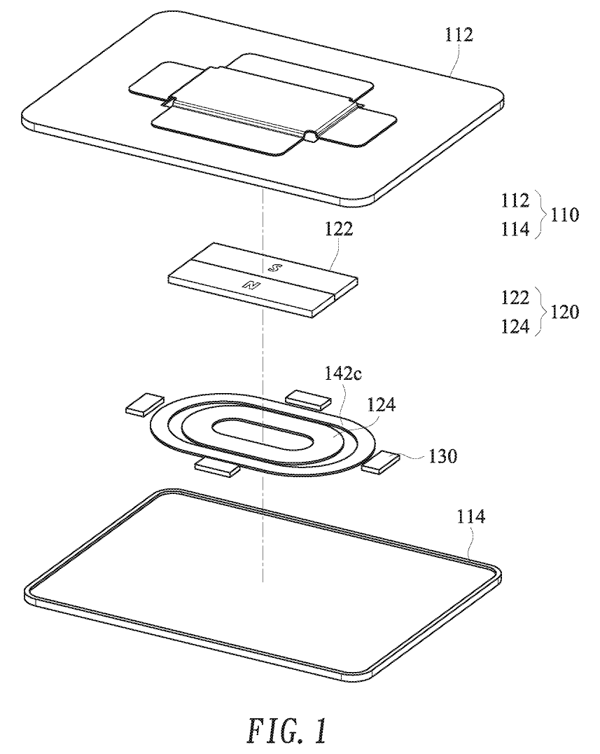

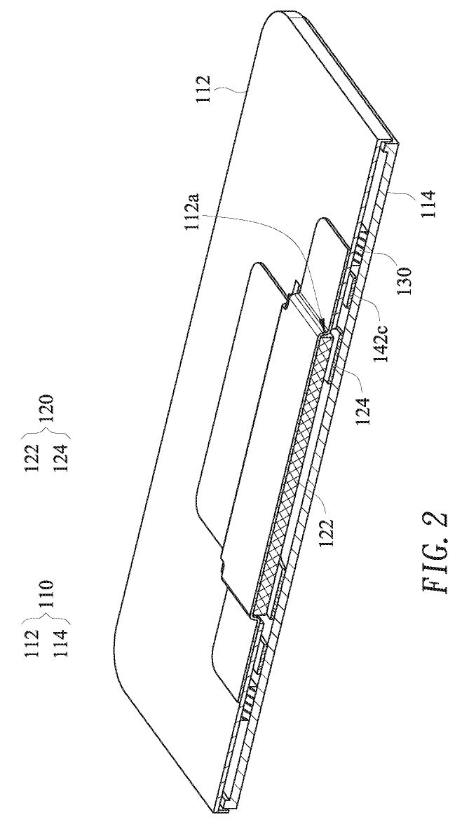

FIG. 1 is an exploded view of a sensing actuator according to an embodiment of the present disclosure. FIG. 2 is a sectional view of the sensing actuator shown in FIG. 1. As shown in FIGS. 1 and 2, the sensing actuator includes a housing 110, a vibration assembly 120, an elastic damping member 130, and a displacement sensing assembly. The displacement sensing assembly may be, for example, an eddy-current sensing assembly. In some embodiments, the sensing actuator may be disposed in a touchpad module, such as a touchpad module of a notebook computer, but the present disclosure is not limited thereto.

The housing 110 includes an upper portion 112 and a lower portion 114. The upper portion 112 is capable of moving downward relative to the lower portion 114. In some embodiments, the length and width of the upper portion 112 are greater than those of the lower portion 114.

The vibration assembly 120 is disposed inside the housing 110. In some embodiments, the vibration assembly 120 includes a permanent magnet 122 and one or more coils 124. The permanent magnet 122 is coupled

to the upper portion 112 of the housing 110. The coil 124 is disposed on the lower portion 114 of the housing 110 and corresponds to the permanent magnet 122. In some embodiments, the upper portion 112 of the housing 110 includes a receiving portion 112a that receives the permanent magnet 122. In some embodiments, the coil 124 is fixed to the lower portion 114 of the housing 110.

In some embodiments, the sensing actuator further includes a controller (not shown) electrically connected to the coil 124 of the vibration assembly 120. When a distance by which the upper portion 112 moves downward (i.e., the displacement of the upper portion 112) reaches a predetermined value, the controller energizes the coil 124 of the vibration assembly 120 to generate a magnetic field (e.g., a time-varying magnetic field), thereby causing the permanent magnet 122 to vibrate and thus causing the upper portion 112 to vibrate. The vibration may be, for example, lateral or vertical.

The elastic damping member 130 is disposed inside the housing 110 and separated from the vibration assembly 120. The elastic damping member 130 is provided to restore the upper portion 112 to its original position after the upper portion 112 moves downward. In some embodiments, the elastic damping member 130 also helps stop the vibration of the upper portion 112 after the vibration occurs. In some embodiments, the elastic damping member 130 includes silicone.

In some embodiments, after the upper portion 112 vibrates, the controller may further energize the coil 124 of the vibration assembly 120 to generate a counterwave that cancels the vibration, helping the permanent magnet 122 and the upper portion 112 stop vibrating.

The displacement sensing assembly is disposed inside the housing 110 and separated from both the vibration assembly 120 and the

elastic damping member 130. In some embodiments, the upper portion 112 of the housing 110 is made of conductive metal, and the displacement sensing assembly is an eddy-current displacement sensing assembly. The eddy-current displacement sensing assembly includes one or more coils 142c disposed on the lower portion 114 of the housing 110 and configured to be energized to generate a magnetic field. When the upper portion 112 moves downward, the upper portion 112 approaches the coils 142c, resulting in an increased eddy current in the upper portion 112. By detecting the change in the eddy current (e.g., the amplitude or phase change of the eddy current), the displacement of the upper portion 112 can be calculated. In some embodiments, the displacement of the upper portion 112 may be converted into a force value.

In some embodiments, the coil 142c of the eddy-current displacement sensing assembly is fixed to the lower portion 114 of the housing 110. In some embodiments, the coil 142c of the eddy-current displacement sensing assembly surrounds the coil 124 of the vibration assembly 120. However, the present disclosure is not limited thereto; in other embodiments, the coil of the vibration assembly may surround the coil of the eddy-current displacement sensing assembly.

The operation of the sensing actuator shown in FIGS. 1 and 2 is explained as follows. A controller (not shown) may be electrically connected to the coil 142c of the eddy-current displacement sensing assembly and energize the coil 142c (e.g., by applying an AC signal to the coil 142c) to generate a magnetic field, inducing eddy currents in the upper portion 112 (made of conductive metal). When the upper portion 112 of the housing 110 moves downward (e.g., when the touchpad is pressed), a distance between the upper portion 112 and the coil 142c decreases, causing the eddy current in the upper portion 112 to increase. The change in eddy current can be

measured by the coil 142c and transmitted to the controller. The controller calculates the displacement of the upper portion 112 and determines whether the displacement reaches a predetermined value (also referred to as a threshold). When the displacement reaches the predetermined value, the controller energizes the coil 124 (e.g., applies a differential AC signal to the coil 124) to generate a magnetic field, thereby causing the permanent magnet 122 to vibrate and thus causing the upper portion 112 to vibrate.

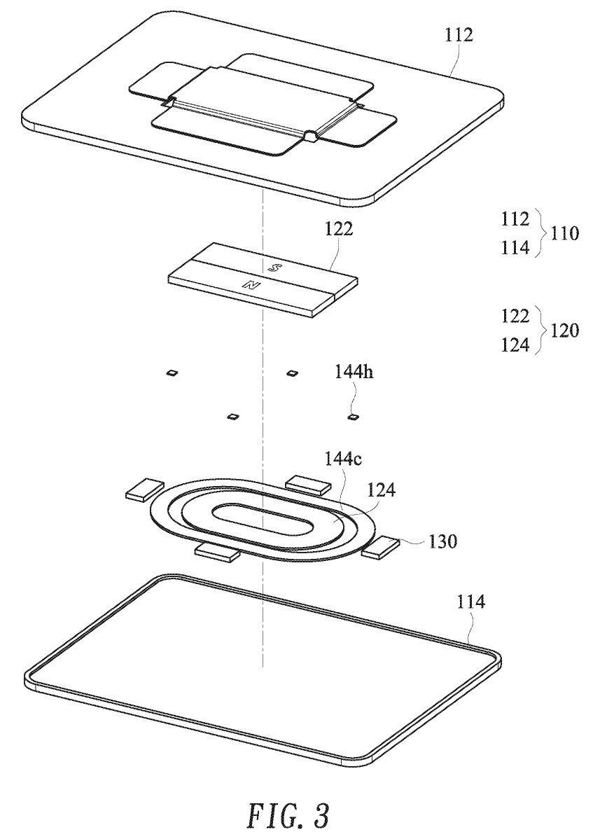

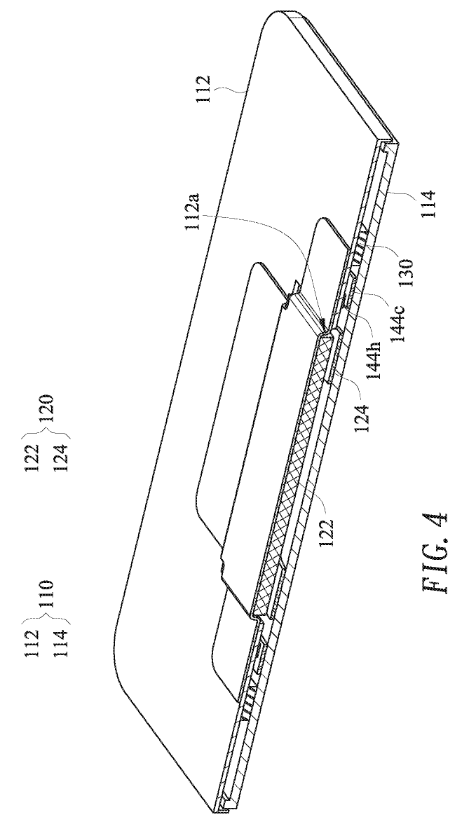

FIG. 3 is an exploded view of a sensing actuator according to an embodiment of the present disclosure. FIG. 4 is a sectional view of the sensing actuator shown in FIG. 3. The embodiment of FIGS. 3 and 4 differs from that of FIGS. 1 and 2 in that the displacement sensing assembly in FIGS. 3 and 4 is a Hall-effect displacement sensing assembly. The Hall-effect displacement sensing assembly includes one or more coils 144c and a Hall element 144h. The coil 144c is disposed on the lower portion 114 of the housing 110 and configured to be energized to generate a magnetic field. The Hall element 144h is coupled to the upper portion 112 of the housing 110 and corresponds to the coil 144c. When the upper portion 112 moves downward, the Hall element 144h moves closer to the coil 144c, causing a polarity change. The displacement of the upper portion 112 can be calculated based on the polarity change. In some embodiments, the upper portion 112 of the housing 110 may be made of conductive metal or insulating material.

In some embodiments, the coil 144c of the Hall-effect displacement sensing assembly is fixed to the lower portion 114 of the housing 110. In some embodiments, the coil 144c of the Hall-effect displacement sensing assembly surrounds the coil 124 of the vibration assembly 120. However, the present disclosure is not limited thereto; in other embodiments, the coil of the vibration assembly may surround the coil of the Hall-effect displacement sensing assembly.

The operation of the sensing actuator shown in FIGS. 3 and 4 is explained as follows. A controller (not shown) may be electrically connected to the coil 144c of the Hall-effect displacement sensing assembly and energize the coil 144c (e.g., by applying an AC signal to the coil 144c) to generate polarity. When the upper portion 112 of the housing 110 moves downward (e.g., when the touchpad is pressed), a distance between the upper portion 112 and the coil 144c decreases, the Hall element 144h detects the polarity change and calculates the displacement of the upper portion 112, then transmits the information to the controller. The controller determines whether the displacement reaches a predetermined value (also referred to as a threshold). When the displacement reaches the predetermined value, the controller energizes the coil 124 (e.g., applies a differential AC signal to the coil 124) to generate a magnetic field, thereby causing the permanent magnet 122 to vibrate and thus causing the upper portion 112 to vibrate.

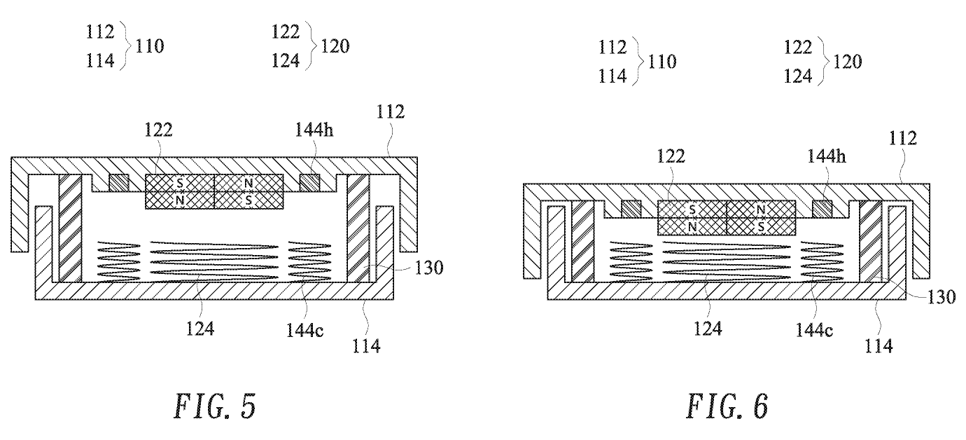

FIG. 5 is a sectional view of a sensing actuator according to an embodiment of the present disclosure. FIG. 6 is a sectional view of the upper portion of the housing of the sensing actuator in FIG. 5 after being pressed downward. The embodiment of FIGS. 5 and 6 also adopts a Hall-effect displacement sensing assembly. As shown in FIGS. 5 and 6, when the upper portion 112 of the housing 110 is pressed downward, the elastic damping member 130 is compressed, reducing the distance between the upper portion 112 and the coil 144c. The displacement of the upper portion 112 can be calculated using the Hall-effect displacement sensing assembly. As shown in FIGS. 6 and 5, when the upper portion 112 of the housing 110 is no longer pressed, the elastic force of the elastic damping member 130 restores the upper portion 112 to its original position.

However, the above are only the preferred embodiments of the present disclosure, and should not be used to limit the scope of

implementation of the present disclosure, that is, simple equivalent changes and modifications made in accordance with claims and description of the present disclosure are still within the scope of the present disclosure. In addition, any embodiment of the present disclosure or claim does not need to achieve all the objectives or advantages disclosed in the present disclosure. In addition, the abstract and the title are not intended to limit the scope of claims of the present disclosure.

What is claimed is:

1. A sensing actuator, comprising:
a housing, having an upper portion and a lower portion, the upper portion being movable downward relative to the lower portion;
a vibration assembly, disposed in the housing;
an elastic damping member, disposed in the housing and separated from the vibration assembly, the elastic damping member being configured to restore the upper portion to its original position after the upper portion moves downward; and
a displacement sensing assembly, disposed in the housing and separated from both the vibration assembly and the elastic damping member, wherein the displacement sensing assembly is an eddy-current displacement sensing assembly or a Hall-effect displacement sensing assembly.

2. The sensing actuator of claim 1, wherein the upper portion of the housing is made of a conductive metal, and the displacement sensing assembly is the eddy-current displacement sensing assembly, and the eddy-current displacement sensing assembly comprises:
a coil, disposed on the lower portion of the housing and configured to be energized to generate a magnetic field, wherein when the upper portion moves downward, the upper portion approaches the coil.

3. The sensing actuator of claim 1, wherein the displacement sensing assembly is the Hall-effect displacement sensing assembly, and the Hall-effect displacement sensing assembly comprises:
a coil, disposed on the lower portion of the housing and configured to be energized to generate a magnetic field; and
a Hall element, coupled to the upper portion of the housing and corresponding to the coil, wherein when the upper portion moves downward, the Hall element approaches the coil.

4. The sensing actuator of claim 1, wherein the vibration assembly comprises:
a permanent magnet, coupled to the upper portion of the housing; and
a coil, disposed on the lower portion of the housing and corresponding to the permanent magnet.

5. The sensing actuator of claim 4, further comprising:
a controller, electrically connected to the coil of the vibration assembly, wherein when a distance by which the upper portion moves downward reaches a predetermined value, the controller energizes the coil of the vibration assembly to generate a magnetic field, thereby causing the permanent magnet to vibrate and thus causing the upper portion to vibrate.

6. The sensing actuator of claim 5, wherein the elastic damping member is further configured to help stop the vibration of the upper portion after the upper portion vibrates.

7. The sensing actuator of claim 4, wherein the upper portion of the housing comprises a receiving portion that receives the permanent magnet.

8. The sensing actuator of claim 4, wherein the eddy-current displacement sensing assembly or the Hall-effect displacement sensing assembly comprises a coil, and the coil of the eddy-current or Hall-effect displacement sensing assembly surrounds the coil of the vibration assembly.

9. The sensing actuator of claim 4, wherein the eddy-current displacement sensing assembly or the Hall-effect displacement sensing assembly comprises a coil, and the coil of the vibration assembly surrounds the coil of the eddy-current or Hall-effect displacement sensing assembly.

10. The sensing actuator of claim 1, wherein the eddy-current displacement sensing assembly or the Hall-effect displacement sensing assembly comprises a coil, and the coil of the eddy-current or Hall-effect displacement sensing assembly is fixed to the lower portion of the housing.
